(19) United States
(12) Patent Application Publication
(10) Pub. No.: US 2009/0153688 A1
(43) Pub. Date: Jun. 18, 2009

(54) Digital Video Cable Driver

(75) Inventor: Vasilis Papanikolaou, Toronto (CA)

Correspondence Address: PATENT GROUP 2N;JONES DAY, NORTH POINT, 901 LAKESIDE AVENUE, CLEVELAND, OH, 44114, US

(73) Assignee: Gennum Corporation

(21) Appl. No.: 11/955,929

(22) Filed: Dec. 13, 2007

(51) Int. Cl. H04N 5/228; H03F 3/45; H03M 9/00

(52) U.S. Cl. 348/222.1; 330/252; 330/253; 341/101; 348/E05.031

(57) ABSTRACT

In accordance with the teachings described herein, a digital video cable driver is provided that includes an input stage, an output stage and an amplification stage. The input stage converts a pair of differential input voltages into a control current. The output stage generates a digital output voltage for transmission over a cable. The amplification stage responds to the control current to control a voltage swing of the digital output voltage as a function of the control current. The amplification stage may include a transistor circuit that varies the digital output voltage in proportion to variations in the control current to cause the voltage swing, wherein the control current causes one or more transistors in the transistor circuit to remain in a saturated state during operation of the digital video cable driver.

### FIELD

The technology described in this patent document relates generally to video and data communications. More particularly, the technology relates to digital video cable drivers.

### BACKGROUND AND SUMMARY

A digital video cable driver is used to transmit digital video signals over a transmission medium. When used in the motion picture or television industries the operating parameters of a digital video cable driver must typically comply with the standards published by the Society of Motion Picture and Television Engineering (SMPTE). Many video cable drivers employ a standard differential amplifier circuit having a differential pair of transistors in the output stage. This configuration is often used because of its simplicity and its inherent symmetry. However, when a large output swing is desired, such as in SMPTE applications, a cable driver with a standard differential amplifier circuit often has supply headroom issues, particularly when employing nanometer technologies. It would thus be advantageous to provide a digital video cable driver with more headroom at lower supply voltages.

In accordance with the teachings described herein, a digital video cable driver is provided that includes an input stage, an output stage and an amplification stage. The input stage converts a pair of differential input voltages into a control current. The output stage generates a digital output voltage for transmission over a cable. The amplification stage responds to the control current to control a voltage swing of the digital output voltage as a function of the control current. The amplification stage may include a transistor circuit that varies the digital output voltage in proportion to variations in the control current to cause the voltage swing, wherein the control current causes one or more transistors in the transistor circuit to remain in the linear region during operation of the digital video cable driver.

### BRIEF DESCRIPTION OF THE DRAWINGS

FIG. 1 is a diagram of an example digital video cable driver.

FIG. 2 is a diagram of another example digital video cable driver.

FIG. 3 is an eye diagram depicting the voltage swing of the digital output voltage for the cable driver shown in FIG. 1.

FIG. 4 is a diagram illustrating another example digital video cable driver.

FIG. 5 is a diagram illustrating an example digital video cable driver having multiple positive outputs.

FIG. 6 depicts a video serializer circuit that generates a serial video signal from parallel video and parallel clock inputs.

FIG. 7 depicts a digital video camera that generates a serial data output from sensed images.

### DETAILED DESCRIPTION

FIG. 1 is a block diagram of an example digital video cable driver 10 that includes an input stage 12, an amplification stage 14 and an output stage 16. The input stage is a transconductance amplifier that converts a pair of differential input voltages into a single-ended control current (I_{C}). The amplification stage is a current amplifier that amplifies the control current (I_{C}) to generate an output current (Iout). The output stage 16 is a transimpedance amplifier that converts the single-ended output current (Iout) into a digital output voltage (Vout). In operation, the digital video cable driver 10 controls the voltage swing of the digital output voltage (Vout) as a function of the control current (I_{C}).

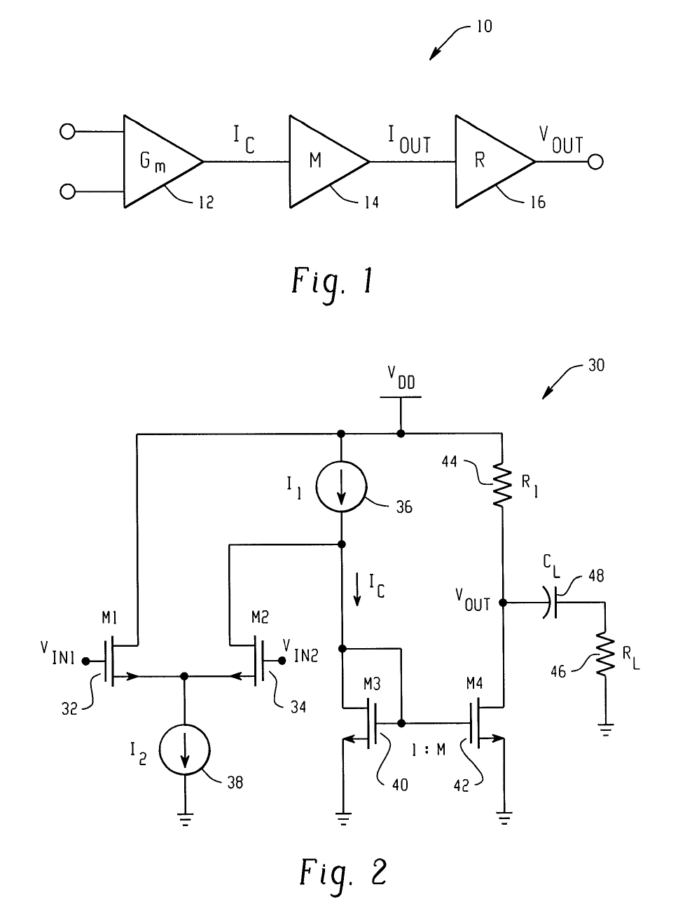

FIG. 2 is a diagram of another example digital video cable driver 30. The cable driver 30 includes an input stage, an amplification stage and an output stage. The input stage includes a first pair of NMOS transistors 32, 34 (M₁ and M₂), a first current source 36 (I₁) and a second current source 38 (I₂). The amplification stage includes a second pair of NMOS transistors 40, 42 (M₃ and M₄). The output stage includes a pull-up resistor 44 (R₁). Also illustrated is a load resistance 46 (R_{L}) and an ac-coupling capacitance 48 (C_{L}). In operation, the input stage converts a pair of differential input voltages (V_{IN1} and V_{IN2}) into a control current (I_{C}) that is input to the amplification stage. The amplification stage amplifies the control current (I_{C}) to control the voltage swing at the output (V_{OUT}) of the output stage.

The input stage converts the differential input voltages (V_{IN1} and V_{IN2}) into the control current (I_{C}). The differential input voltages (V_{IN1} and V_{IN2}) vary the control current (I_{C}) as a function of the difference between the currents generated by the first current source (I₁) and the second current source (I₂). Specifically, when the first input voltage (V_{IN1}) is in a logic high state (causing M₁ to turn on) and the second input voltage (V_{IN2}) is in a logic low state (causing M₂ to turn off), then the control current (I_{C}) is equal to the current generated by the first current source (I₁). When the first input voltage (V_{IN1}) is in a logic low state (causing M₁ to turn off) and the second input voltage (V_{IN2}) is in a logic high state (causing M₂ to turn on), then the control current (I_{C}) is limited by the second current source (I₂), such that the control current is equal to the difference between the first and second current sources (I_{C}=I₁−I₂).

The control current (IC) is coupled to the gate terminals of the transistor pair 40, 42 (M₃ and M₄) in the amplification stage. In addition, the control current (I_{C}) is input to the source terminal of transistor M₃, and the drain terminal of transistor M₄ is coupled to the output node (V_{OUT}) of the cable driver 30. Thus, the control current (I_{C}) passes through the current carrying terminals of transistor M₃ and is amplified by a gain (M) through the current carrying terminals of transistor M₄. As a result, variations in the control current (I_{C}) are reflected in the amplified current through transistor M₄, which controls the voltage swing of the digital output voltage (V_{OUT}).

In order to achieve a high data rate (e.g., for GHz operation), currents I₁ and I₂ are selected to prevent the transistors M₃ and M₄ in the amplification stage from staying in the linear region. That is, the difference between I₁ and I₂ is large enough that the control current (I_{C}) during a logic level “1” (V_{OUT}-High) is high enough to keep the transistors M₃ and M₄ in a saturated state.

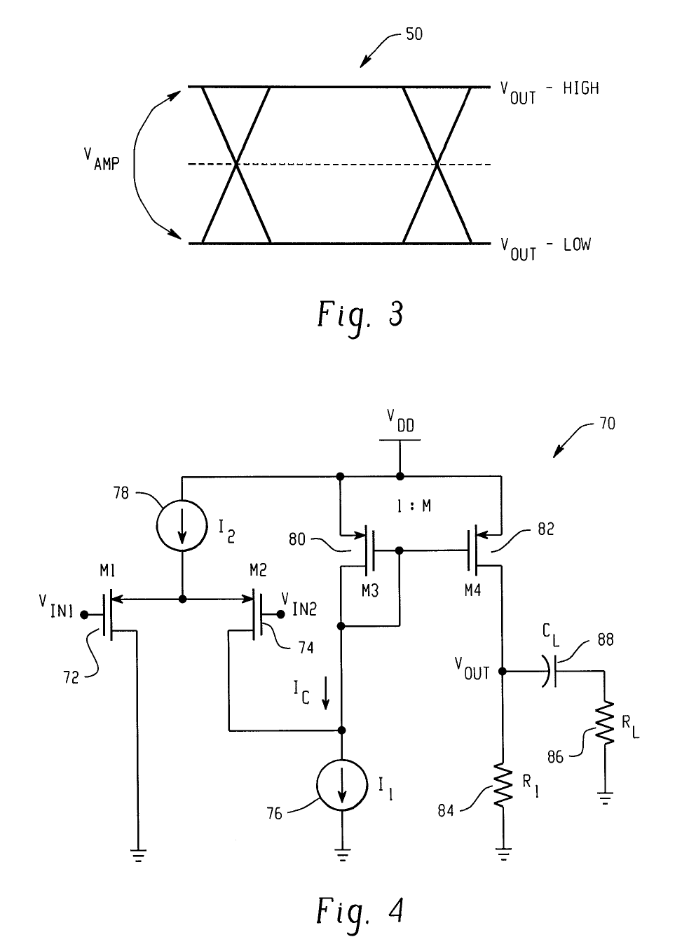

An eye diagram 50 of the digital output voltage (V_{OUT}) is illustrated at FIG. 3. The eye diagram 50 depicts the voltage swing (V_{AMP}) of the digital output voltage (V_{OUT}) for the cable driver 30 shown in FIG. 1. V_{OUT}-HIGH is the digital output voltage (V_{OUT}) during a logic level “1” and V_{OUT}-LOW is the digital output voltage (V_{OUT}) during a logic level “0”. Cross-referencing FIGS. 2 and 3, the following equations represent the voltage swing (V_{AMP}) and digital output voltage (V_{OUT}) for the cable driver 30. Equations are provided for both a loaded and unloaded condition (i.e., with and without R_{L} and C_{L}).

Unloaded Condition:

V_{AMP}(unloaded)=I₂*M*R_{L}

V_{OUT}-HIGH(unloaded)=V_{DD}−(I₁−I₂)*M*R_{L}

V_{OUT}-LOW(unloaded)=V_{DD}−I₁*M*R_{L}

Loaded Condition:

V_{AMP}(loaded)=I₂*M*R_{L}/2

V_{OUT}-HIGH(loaded)=V_{OUT}-HIGH(unloaded)−V_{AMP}(unloaded)/2+V_{AMP}(loaded)/2

VOUT-LOW(loaded)=V_{OUT}-HIGH(unloaded)−V_{AMP}(unloaded)/2−V_{AMP}(loaded)/2

To illustrate the operation of the cable driver 30, consider an example in which the following values are implemented in the circuit 30:

V_{DD}=2.5V

M=2.5

I₁=9.6 mA

I₂=8.8 mA

R_{L}=750Ω

In the above example, the resultant output voltage swing (V_{AMP}) and digital output voltages (V_{OUT}) are as follows:

Unloaded Condition:

V_{AMP}(unloaded)=1.65 V

V_{OUT}-HIGH(unloaded)=2.35 V

V_{OUT}-LOW(unloaded)=0.70 V

Loaded Condition:

V_{AMP}(loaded)=0.825 V

V_{OUT}-HIGH(loaded)=1.938 V

VOUT-LOW(loaded)=1.113 V

As shown above, the output voltage swing (V_{AMP}) in this example is 1.65 V when the circuit 30 is unloaded, and when terminated to a load (R_{L}) through an ac-coupling capacitor (C_{L}), the circuit results in a 825 mVpp swing. Significantly, this example configuration provides the 800 mV swing required by the SMPTE standards at the relatively low source voltage (V_{DD}) of 2.5 V. Other advantages over a typical differential cable driver circuit may also be achieved by the digital video cable driver 30 architecture shown in FIG. 2.

For instance, the use of a current folding circuit utilizing NMOS transistors provides additional headroom in comparison to a typical cable driver circuit with a differential output stage and enables the circuit to be integrated into CMOS, reducing the overall BOM cost of an SMPTE compliant driver. With this additional headroom, 900 mVpp-1000 mVpp output voltage swings are achievable within the constraints of a 2.5 V supply. In addition, the increased headroom allows for the use of a smaller transistor at the output stage. Further, by operating farther into the linear region due to the extra headroom, the sensitivity of the supply voltage on return loss may be reduced.

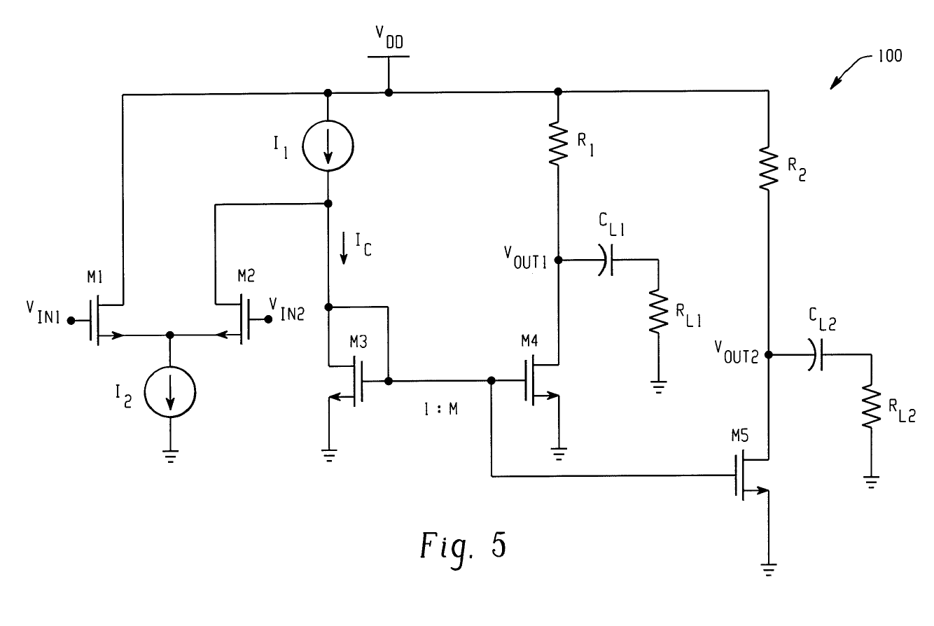

In addition, the provision of a digital output stage, along with the potential for integration into CMOS, provides the ability to turn off the amplification stage when there is no active input, thus improving ORL. The output stage can easily be placed in a power down mode, without any additional circuitry, by forcing the output to be in a logic high state causing the current drawn from the output state to be very low. Other advantages over a typical differential cable driver may include improved power consumption, a reduction in the necessary silicon footprint, and the availability of multiple positive outputs (see, e.g., FIG. 5).

FIG. 4 is a diagram illustrating another example digital video cable driver 70. This example 70 is similar to the digital video cable driver depicted in FIG. 2, except that it utilizes PMOS transistors instead of NMOS transistors. Specifically, the input stage includes a first pair of PMOS transistors 72, 74 (M₁ and M₂), a first current source 76 (I₁) and a second current source 78 (I₂). The amplification stage includes a second pair of PMOS transistors 80, 82 (M₃ and M₄), and the output stage includes a pull-down resistor 84 (R₁). Also illustrated are the load resistance R_{L} and an ac-coupling capacitor 88 (C_{L}). In operation, the input stage converts a pair of differential input voltages (V_{IN1} and V_{IN2}) into a control current (I_{C}), which varies the current in the amplification stage. The amplification stage amplifies the control current (Ic) to control the voltage swing at the output (V_{OUT}) of the output stage.

In this example, the current folding circuit in the input stage varies the control current (I_{C}) through the amplification stage as a function of the differential input voltages (V_{IN1} and V_{IN2}). Specifically, when the first input voltage (V_{IN1}) is in a logic low state (causing M₁ to turn on) and the second input voltage (V_{IN2}) is in a logic high state (causing M₂ to turn off), then the control current (I_{C}) is equal to the current generated by the first current source (I₁). When the first input voltage (V_{IN1}) is in a logic high state (causing M₁ to turn off) and the second input voltage (V_{IN2}) is in a logic low state (causing M₂ to turn on), then the control current (I_{C}) is limited by the second current source (I₂), such that the control current (I_{C}) is equal to the difference between the first and second current sources (I_{C}=I₁−I₂).

The control current (I_{C}) is coupled to the gate terminals of the transistor pair 80, 82 (M₃ and M₄) in the amplification stage. In addition, the control current (I_{C}) controls the current flow through the current carrying terminals of transistor M₃, which is reflected in the amplified current through transistor M₄. Variations in the control current (I_{C}) thus control the voltage swing of the digital output voltage (V_{OUT}) at the drain terminal of transistor M₄.

FIG. 5 is a diagram illustrating an example digital video cable driver 100 having multiple positive outputs (V_{OUT1} and V_{OUT2}). This example is similar to the digital video cable driver shown in FIG. 2, except that it includes an additional positive output (V_{OUT2}). This is achieved by providing an additional output transistor (M₅) in the amplification stage. In operation, the amplification stage responds to a control current (I_{C}) that is varied as a function of differential input voltages (V_{IN1} and V_{IN2}). The amplification stage amplifies the control current (I_{C}) to control the voltage swings at each of the multiple positive outputs (V_{OUT1} and V_{OUT2}).

The input stage in this example operates the same as the input stage in the example of FIG. 2. In this embodiment, however, the control current (I_{C}) is also coupled to the gate terminal of one or more additional output transistors (M₅) in the amplification stage. In this way, variations in the control current are reflected in the amplified currents through each of the multiple output transistors (M₄ and M₅). Variations in the control current (I_{C}) thus control the voltage swing at each of the multiple positive outputs (V_{OUT1} and V_{OUT2}).

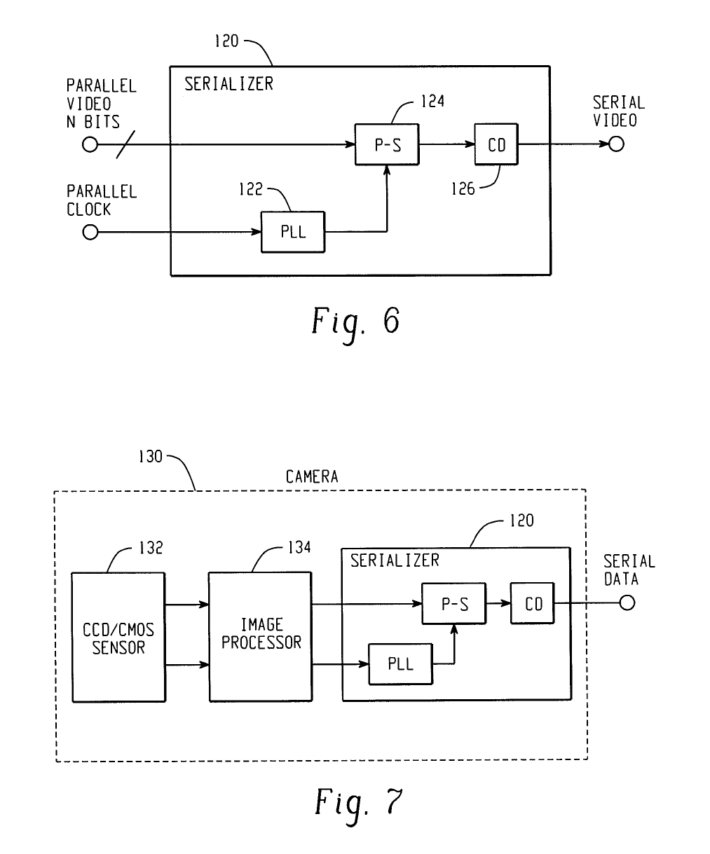

FIGS. 6 and 7 are block diagrams depicting example systems that may include a digital video cable driver as described herein. FIG. 6 depicts a video serializer circuit 120 that generates a serial video signal from parallel video and parallel clock inputs. The video serializer circuit 120 includes a phase locked loop circuit (PLL) 122, a parallel-to-serial converter 124 and a digital video cable driver 126. The parallel-to-serial converter 124 converts the parallel video input into a differential video signal using a retimed clock signal from the PLL 122. The differential video signal is then converted to a single-ended video signal by the cable driver 126 for transmission over a transmission medium, for instance as described above with reference to FIG. 2 or 4.

FIG. 7 depicts a digital video camera 130 that generates a serial data output from sensed images. The digital video camera 122 includes an image sensor 132, such as a CCD or CMOS sensor, an image processor 134 and a video serializer circuit 120. The image sensor 132 converts visual images into a video signal that is processed by the image processor 134. The image processor 134 performs one or more video processing functions to the video signal and outputs a parallel video signal and a parallel clock signal to the video serializer 120. The video serializer 120 then converts the parallel video signal into a serial video signal and amplifies the signal for transmission over a transmission medium, such as a coaxial cable, as described above with reference to FIG. 6.

This written description uses examples to disclose the invention, including the best mode, and also to enable a person skilled in the art to make and use the invention. The patentable scope of the invention may include other examples that occur to those skilled in the art. For example, other embodiments could include one or more bipolar transistors or a combination of biplolar and CMOS transistors.

It is claimed:

1. A digital video cable driver, comprising:
an input stage that converts a pair of differential input voltages into a control current;
an output stage that generates a digital output voltage for transmission over a cable; and
an amplification stage that responds to the control current to control a voltage swing of the digital output voltage as a function of the control current,
the amplification stage including a transistor circuit that varies the digital output voltage in proportion to variations in the control current to cause the voltage swing, wherein the control current causes one or more transistors in the transistor circuit to remain in the linear region during operation of the digital video cable driver.

2. The digital video cable driver of claim 1, wherein the transistor circuit includes a first transistor and a second transistor that are driven by the control current such that a first current passing through the first transistor is amplified to generate a second current passing through the second transistor, and wherein variation in the second current controls the voltage swing of the digital output voltage.

3. The digital video cable driver of claim 2, wherein the control current is input to a current carrying terminal of the first transistor to provide the first current through the first transistor and amplified as the second current through the second transistor, such that variation in the control current controls the voltage swing of the digital output voltage.

4. The digital video cable driver of claim 3, wherein the control current prevents the first and second transistors from leaving the linear region during operation of the digital video cable driver.

5. The digital video cable driver of claim 1, wherein the transistor circuit includes exclusively NMOS transistors.

6. The digital video cable driver of claim 1, wherein the transistor circuit includes exclusively NPN BiPolar transistors.

7. The digital video cable driver of claim 1, wherein the input stage includes a current folding circuit that controls an amount of current input to the amplification stage as the control current.

8. The digital video cable driver of claim 7, wherein the current folding circuit includes:
a first current source that generates a first current;
a second current source that generates a second current; and
a second transistor circuit controlled by the differential input voltages that varies the control current as a function of a difference between the first current and the second current.

9. The digital video cable driver of claim 1, further comprising:
one or more additional output stages that generate one or more additional digital output voltages;
wherein the amplification stage responds to the control current to control voltage swings of the one or more additional digital output voltages.

10. A video serializer, comprising:
a parallel-to-serial converter that receives a parallel video signal and converts the parallel video signal into a differential video signal; and
a digital video cable driver that converts the differential video signal into a single-ended video signal for transmission over a cable, the digital video cable driver including:
an input stage that converts the differential video signal into a control current;
an output stage that generates the single-ended video signal; and
an amplification stage that responds to the control current to control a voltage swing of the single-ended video signal as a function of the control current,
the amplification stage including a transistor circuit that varies the single-ended video signal in proportion to variations in the control current to cause the voltage swing, wherein the control current causes one or more transistors in the transistor circuit to remain in a saturated state during operation of the digital video cable driver.

11. A digital video camera, comprising:
an image sensor that converts an optical input into a video signal;
an image processor that performs one or more video processing functions to the video signal and generates a parallel video signal;
a parallel-to-serial converter that receives the parallel video signal and converts the parallel video signal into a differential video signal; and
a digital video cable driver that converts the differential video signal into a single-ended video signal for transmission over a cable, the digital video cable driver including:
an input stage that converts the differential video signal into a control current;
an output stage that generates the single-ended video signal; and
an amplification stage that responds to the control current to control a voltage swing of the single-ended video signal as a function of the control current,
the amplification stage including a transistor circuit that varies the single-ended video signal in proportion to variations in the control current to cause the voltage swing, wherein the control current causes one or more transistors in the transistor circuit to remain in a linear region during operation of the digital video cable driver.
